(19) United States
(12) Patent Application Publication
(10) Pub. No.: US 2020/0227323 A1
(43) Pub. Date: Jul. 16, 2020

(54) ISOLATION STRUCTURES OF FINFET SEMICONDUCTOR DEVICES

(71) Applicant: GLOBALFOUNDRIES INC., GRAND CAYMAN (KY)

(72) Inventors: HUI ZANG, Guilderland, NY (US); RUILONG XIE, Niskayuna, NY (US); JESSICA MARY DECHENE, Watervliet, NY (US)

(21) Appl. No.: 16/246,536

(22) Filed: Jan. 13, 2019

(51) Int. Cl. H01L 21/8234; H01L 27/088; H01L 29/66; H01L 21/762

(52) U.S. Cl. CPC H01L 21/823481; H01L 27/0886; H01L 29/6653; H01L 29/66545; H01L 21/76224; H01L 21/823431

(57) ABSTRACT

A method of fabricating a semiconductor device is provided, which includes providing sacrificial gate structures over a plurality of fins, wherein the sacrificial gate structures include a first sacrificial gate structure and a second sacrificial gate structure. A fin cut process is performed to form a fin cut opening in the first sacrificial gate structure. A gate cut process is performed to form a gate cut opening in the second sacrificial gate structure. A first dielectric layer is deposited in the fin cut opening and the gate cut opening, and the first dielectric layer is recessed in the openings. A second dielectric layer is deposited over the first dielectric layer in the fin cut opening and the gate cut opening to concurrently form a diffusion break structure and a gate cut structure respectively.

### FIELD OF THE INVENTION

The disclosed subject matter relates generally to semiconductor devices, and more particularly to a method of concurrently forming isolation structures of fin-type field effect transistors (FinFETs) and the resulting semiconductor devices.

### BACKGROUND

Scaling of integrated circuit (IC) feature sizes has brought tremendous device miniaturization with performance improvements. One of the primary contributions to IC performance improvement has been at the gate level. As the transistor gates continue to scale, parasitic capacitance in the transistor gates increases and becomes more significant. The parasitic capacitance can be reduced by incorporation of low-k dielectric materials, i.e., dielectric materials having low dielectric constant, in isolation structures at gate level.

Air has a relative k-value close to 1, the lowest dielectric constant possible. Incorporating of air into a dielectric material to increase porosity is an attractive method to achieve a lower k-value in the dielectric material. However, incorporating such porous dielectric materials presents many challenges. Such porous dielectric materials typically exhibit weak mechanical properties and low resistance against chemical attack, increasing integration difficulty.

As described above, there is a strong need to present devices and methods of fabricating robust isolation structures having low parasitic capacitance by incorporating porous low-k dielectric material at gate level.

### SUMMARY

To achieve the foregoing and other aspects of the present disclosure, a method of concurrently forming a single diffusion break structure and gate cut structures of FinFET semiconductor devices and the resulting semiconductor devices are presented.

According to an aspect of the disclosure, a method of fabricating a semiconductor device is provided, which includes providing sacrificial gate structures over a plurality of fins, wherein the sacrificial gate structures include a first sacrificial gate structure and a second sacrificial gate structure. A fin cut process is performed to form a fin cut opening in the first sacrificial gate structure. A gate cut process is performed to form a gate cut opening in the second sacrificial gate structure. A first dielectric layer is deposited in the fin cut opening and the gate cut opening, and the first dielectric layer is recessed in the openings. A second dielectric layer is deposited over the first dielectric layer in the fin cut opening and the gate cut opening to concurrently form a diffusion break structure and a gate cut structure respectively.

According to another aspect of the disclosure, a semiconductor device is provided, which includes a first gate structure, a second gate structure, a third gate structure, a fourth gate structure, a diffusion break structure and a gate cut structure. The diffusion break structure is positioned between the first gate structure and the second gate structure, and the gate cut structure is positioned between the third gate structure and the fourth gate structure. The diffusion break structure and the gate cut structure, respectively, include a first dielectric layer in a lower portion thereof and a second dielectric layer over the first dielectric layer.

According to yet another aspect of the disclosure, a semiconductor device is provided, which includes a first gate structure, a second gate structure and a diffusion break structure. The diffusion break structure is positioned between the first gate structure and the second gate structure. The diffusion break structure includes a first dielectric layer in a lower portion thereof and a second dielectric layer over the first dielectric layer.

### BRIEF DESCRIPTION OF THE DRAWINGS

The embodiments of the present disclosure will be better understood from a reading of the following detailed description, taken in conjunction with the accompanying drawings:

FIG. 1 is a top view of a FinFET device, according to an embodiment of the disclosure.

FIGS. 2A-11B are cross-sectional views of a FinFET device (taken along lines A-A′ and B-B′ as indicated in FIG. 1), depicting a method of concurrently forming a single diffusion break structure and gate cut structures, according to an embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the disclosure. Additionally, elements in the drawings are not necessarily drawn to scale. For example, the dimensions of some of the elements in the drawings may be exaggerated relative to other elements to help improve understanding of embodiments of the disclosure. The same reference numerals in different drawings denote the same elements, while similar reference numerals may, but do not necessarily, denote similar elements.

### DETAILED DESCRIPTION

Various embodiments of the disclosure are described below. The embodiments disclosed herein are exemplary and not intended to be exhaustive or limiting to the disclosure.

The disclosure relates to a method of fabricating robust isolation structures in semiconductor devices by incorporating a porous low-k dielectric material at gate level and to the resulting devices. As will be readily apparent to those skilled in the art upon a complete reading of this disclosure, the method is applicable to a variety of devices, including, but not limited to, logic devices, memory devices, etc., and the methods disclosed herein may be employed to form N-type or P-type semiconductor devices. The disclosure herein may be employed in forming integrated circuit devices using a variety of so-called 3D devices, such as FinFETs.

Aspects of the disclosure are now described in detail with accompanying drawings. It is noted that like and corresponding elements are referred to by the use of the same reference numerals.

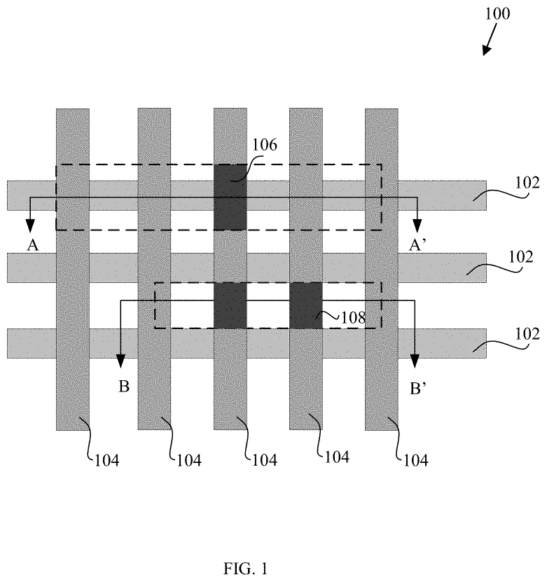

FIG. 1 is a simplified top view of a FinFET device 100, according to an embodiment of the disclosure. The FinFET device 100 includes an array of fins 102, sacrificial gate structures 104 and isolation structures, such as a single diffusion break structure 106 and gate cut structures 108. The sacrificial gate structures 104 are formed over the fins 102. The single diffusion break structure 106 is formed across a short axis of the fin 102 and the gate cut structures 108 are formed across a short axis of the sacrificial gate structures 104. Though three fins and five sacrificial gate structures are illustrated in this embodiment, those skilled in the art would recognize, after a complete reading of the disclosure, the number and placement locations of the fins 102, the sacrificial gate structures 104 and their respective single diffusion break and gate cut structures (106 and 108, respectively) may vary according to the specific design of each FinFET device. In one embodiment of the disclosure, the sacrificial gate structures 104 are formed of amorphous silicon.

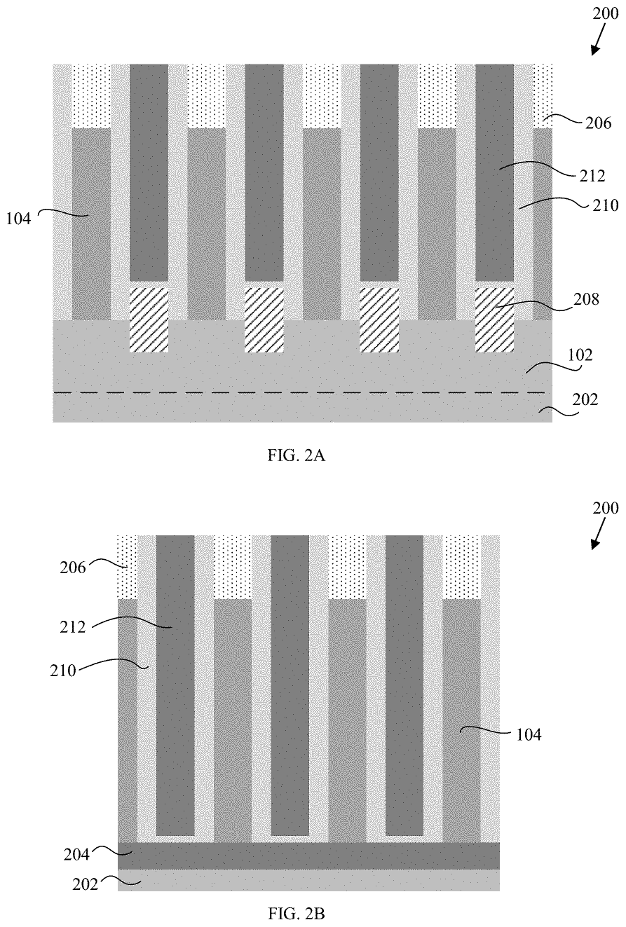

FIGS. 2A-11B are cross-sectional views of a FinFET device 200 (taken along lines A-A′ and B-B′ as indicated in FIG. 1), illustrating a method of concurrently forming single diffusion break and gate cut structures of FinFET devices, according to an embodiment of the disclosure. More specifically, the line A-A′ is taken along a long axis of the fin 102 in a region that is to be “cut” using a fin cut process. The line B-B′ is taken across a short axis of the sacrificial gate structures 104, parallel to the long axis of the fins 102 in a region that is to be “cut” using a gate cut process.

As illustrated in FIGS. 2A and 2B (taken along the lines A-A′ and B-B′ as indicated in FIG. 1), the FinFET device 200 includes a substrate 202 and the fins 102 extending upwards from the substrate 202. Generally, the fins 102 define an active region for forming devices, such as FinFET devices. A first dielectric layer 204 is deposited over the substrate 202, and serves as an isolation layer for the sacrificial gate structures 104 from the semiconductor substrate 202, as illustrated in FIG. 2B. The first dielectric layer 204 is deposited between lower portions of the fins 102 (not shown). A sacrificial gate material is deposited over the first dielectric layer 204 and the fins 102. The sacrificial gate material may include multiple layers (not shown), such as a gate insulation layer (e.g., silicon dioxide) and/or a sacrificial material (e.g., amorphous silicon).

A hard mask layer 206 is deposited over the sacrificial gate material. Using conventional patterning and material removing process operations, the sacrificial gate structures 104 are formed over the fins 102 and the first dielectric layer 204, exposing sidewalls of the sacrificial gate structures 104 and the hard mask layer 206. Trenches are defined between the sacrificial gate structures 104. Portions of the fins 102 in the trenches are recessed and epitaxial source/drain regions 208 (e.g., silicon germanium) are formed, as illustrated in FIG. 2A. The epitaxial regions 208 are formed either in a merged or unmerged condition, and may or may not have the same geometric shape or volume. Gate spacers 210 are conformally deposited on the sidewalls of the sacrificial gate structures 104 and a second dielectric layer 212 is formed over the epitaxial regions 208. A planar surface with exposed hard mask layer 206, gate spacers 210 and second dielectric layer 212 are formed by a conventional planarization process operation process. In one embodiment of the disclosure, the hard mask layer 206 has a thickness ranging from 10 to 50 nm.

As further illustrated in FIG. 2B, the second dielectric layer 212 is formed of a same dielectric material as the first dielectric layer 204. The second dielectric layer 212 may also be formed of a different dielectric material from the first dielectric layer 204. In one embodiment of the disclosure, the first and second dielectric layers (204 and 212, respectively) are formed from a suitable material, such as silicon dioxide, silicon oxynitride (SiON) or tetraethyl orthosilicate (TEOS), and the hard mask layer 206 is formed from a suitable material, such as silicon nitride (SiN). In another embodiment of the disclosure, the gate spacer 210 is preferably formed of a low-k dielectric material, i.e., a dielectric material having a low dielectric constant, and the dielectric material includes SiN, SiON, silicon carbonitride (SiCN), silicon carbide (SiC), silicon oxycarbide (SiOC) or boron-doped silicon carbonitride (SiBCN). In yet another embodiment of the disclosure, the gate spacer 210 has a width in a range of 2 to 10 nm.

The semiconductor substrate 202 may have a variety of configurations, such as the depicted bulk silicon configuration. The substrate 202 may also have a silicon-on-insulator (SOI) configuration. The substrate 202 may include of any appropriate semiconductor material, such as silicon, silicon germanium, silicon carbon, other II-VI or III-V semiconductor compounds and the like. Thus, the terms “substrate” or “semiconductor substrate” should be understood to cover all forms of such materials. The substrate 202 may also have different layers.

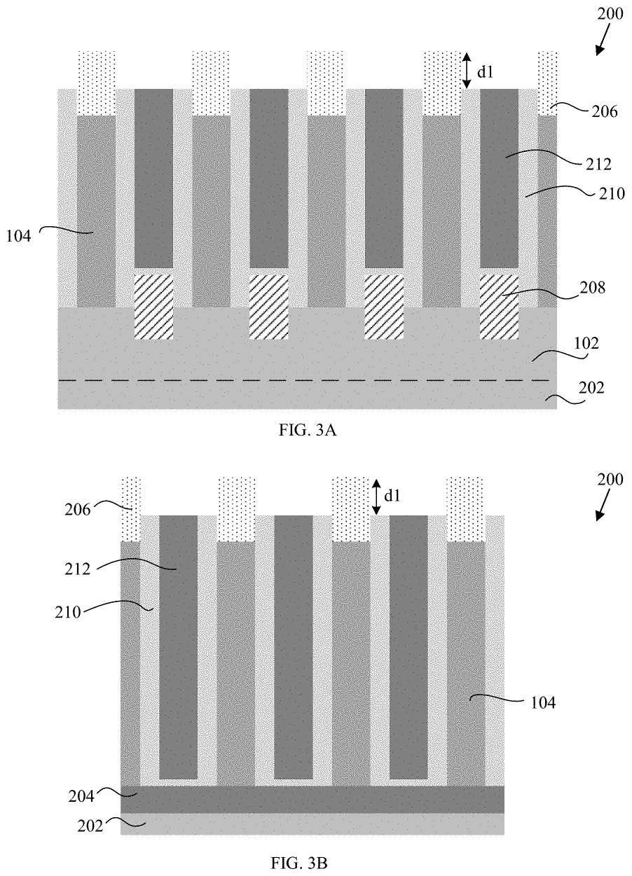

FIGS. 3A and 3B are cross-sectional views of the FinFET device 200 after recessing the gate spacers 210 and the second dielectric layer 212. The gate spacers 210 and the second dielectric layer 212 are recessed below the hard mask layer 206 by conventional material removing process operation to a depth dl ranging from 20 to 50 nm.

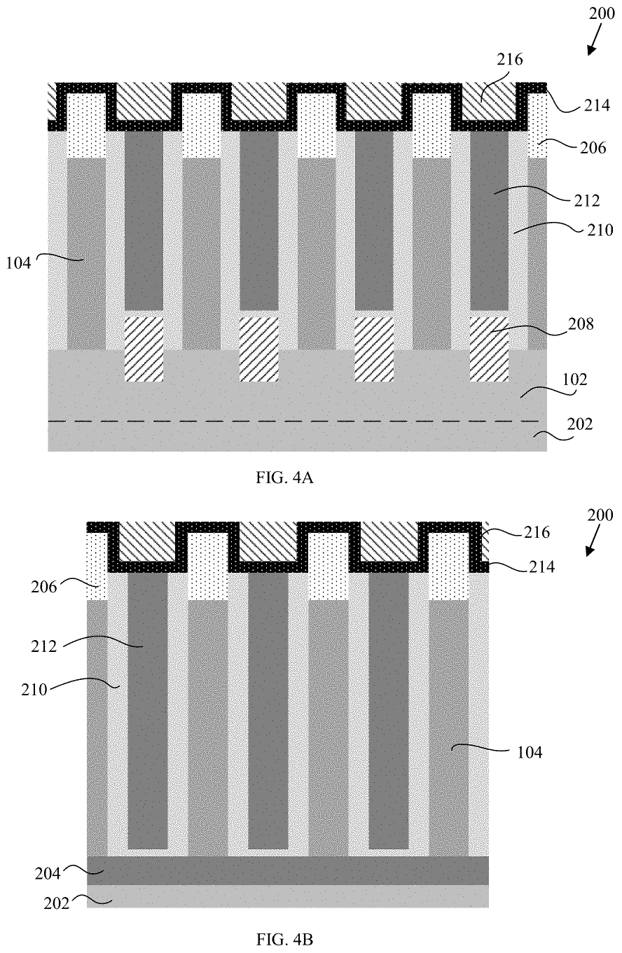

FIGS. 4A and 4B are cross-sectional views of the FinFET device 200 after depositing a first liner 214 and a third dielectric layer 216. The first liner 214 is conformally deposited over the FinFET device 200. The third dielectric layer 216 is deposited over the first liner 214, and a planar surface exposing the first liner 214 is formed by a conventional planarization process operation. In one embodiment of the disclosure, the first liner 214 may be SiN, SiCN, SiC, hafnium oxide (HfO₂), aluminum oxide (AlₓO_{y}, where x and y are in stoichiometric ratio), titanium nitride (TiN) or titanium oxide (TiO₂). In another embodiment of the disclosure, the third dielectric layer 216 may be an oxide material, such as silicon dioxide, SiON or TEOS. In yet another embodiment, the first liner 214 has a thickness ranging from 1 to 15 nm, with a preferred thickness ranging from 5 to 6 nm.

However, those skilled in the art may recognize that many other materials can also be used. What is preferred is that the first liner 214 is sufficiently different from the third dielectric layer 216, such that the two materials will have different removal rates (e.g., etch rates) for different material removing process operations. More preferably, the materials should be different enough such that the first liner 214 is readily removed and the third dielectric layer 216 is not removed at all by a first material removing process operation, while the third dielectric layer 216 is readily removed and the first liner 214 is not removed at all by a second material removing process operation.

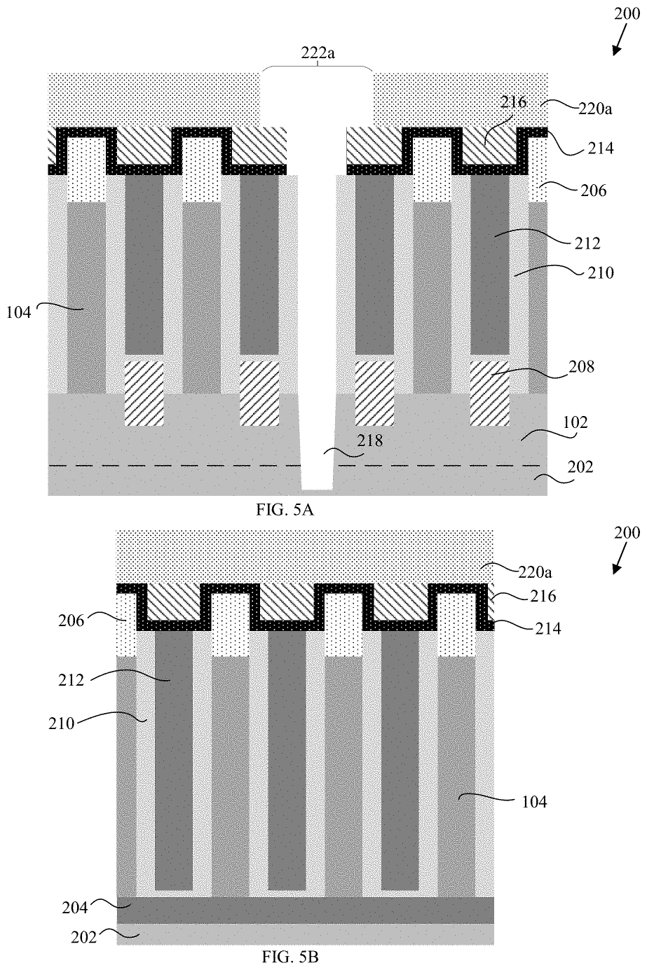

FIGS. 5A and 5B are cross-sectional views of the FinFET device 200 after a plurality of process operations to form a fin cut opening 218. A first organic planarization layer (OPL) 220a is deposited over the FinFET device 200 and a first OPL opening 222a is formed over a selected portion of the sacrificial gate structure 104 by conventional patterning process operation. Portions of the first liner 214, the hard mask layer 206 and the sacrificial gate structure 104 exposed in the first OPL opening 222a are removed by conventional material removing process operation, exposing portions of the gate spacers 210 and a portion of the fin 102. The exposed portion of the fin 102 is subsequently removed, i.e., “cut”, to effectuate the fin cut process, forming the fin cut opening 218. The fin cut opening 218 has a lower portion extended into the substrate 202. Although FIG. 5A illustrates the fin cut opening 218 having tapered sidewalls, alternative embodiments of the fin cut opening 218 may not be tapered. As used herein, the term “tapered” also encompasses “rounded” and “beveled” in which sharp corners or edges are blended to render surfaces less distinct that otherwise form sharp corners and edges.

The employed conventional material removing process operation may be a one-step, a two-step or a multi-step process operation, and is preferred to be selective to the third dielectric layer 216 and the gate spacer 210, i.e., the third dielectric layer 216 and the gate spacer 210 remain predominantly intact during the material removing process operation. As such, the alignment of the fin cut opening 218 is not subjected to patterning limitations and can accurately self-align the fin cut opening 218 between two epitaxial regions 208.

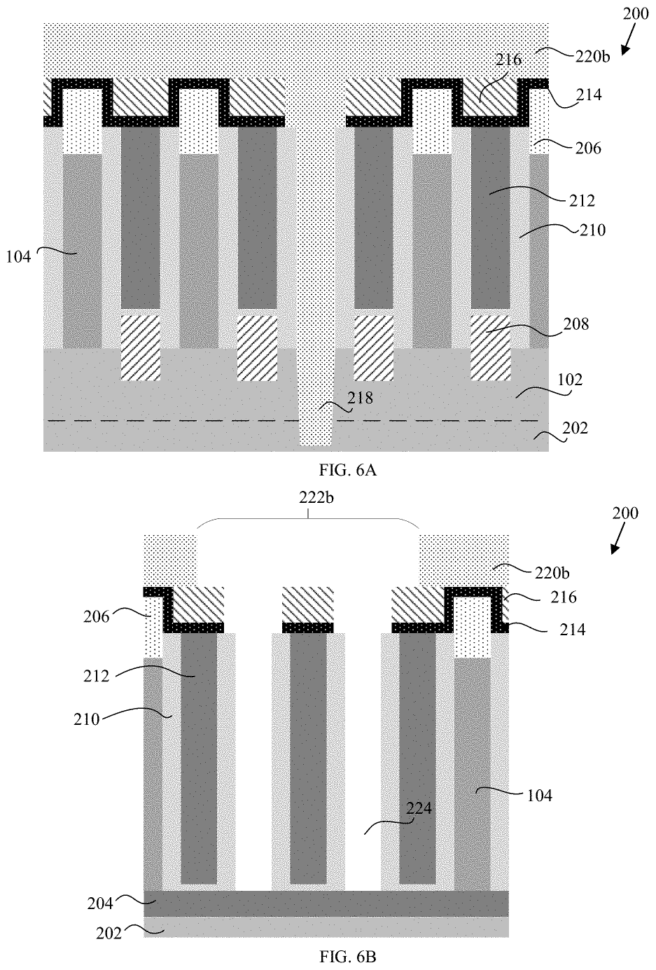

FIGS. 6A and 6B are cross-sectional views of the FinFET device 200 after a plurality of process operations to form gate cut openings 224. The first OPL 220a is stripped after forming the fin cut opening 218 and a second OPL 220b is deposited in the fin cut opening 218 and over the FinFET device 200. A second OPL 222b opening is formed over selected portions of the sacrificial gate structures 104 by conventional patterning process operation. Portions of the first liner 214, the hard mask layer 206 and the sacrificial gate structures 104 exposed in the second OPL opening 222b are removed by conventional material removing process operation, exposing portions of the gate spacers 210 and portions of the first dielectric layer 204. The exposed portions of the sacrificial gate structures 104 is subsequently removed, i.e., “cut”, to effectuate the gate cut process, forming the gate cut openings 224. The conventional material removing process operation employed may be a one-step, a two-step or a multi-step process operation, and is preferred to be selective to the third dielectric layer 216 and the gate spacers 210, i.e., the third dielectric layer 216 and the gate spacers 210 remain predominantly intact during the material removing process operation.

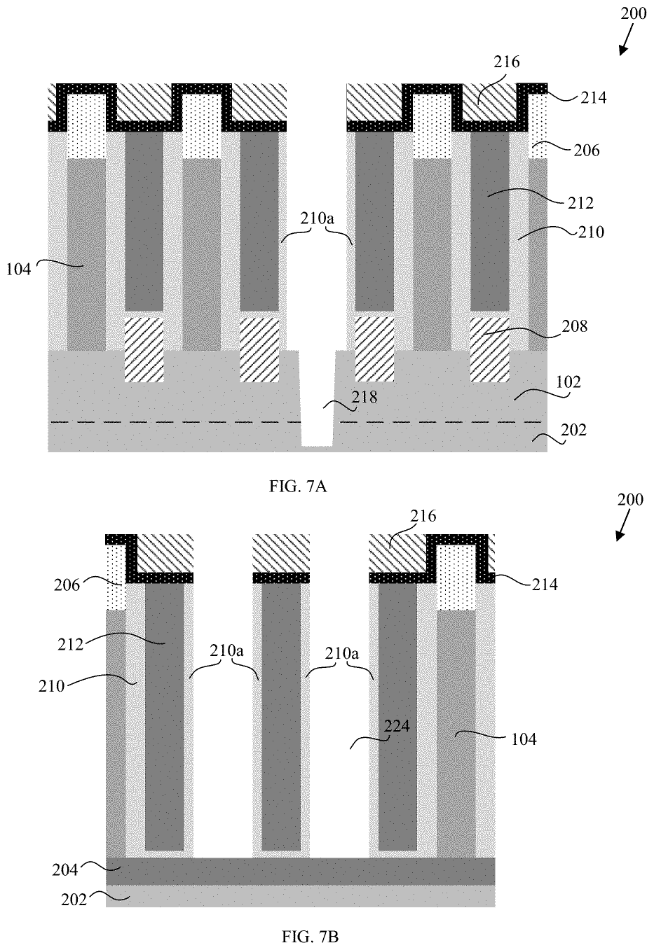

In alternative embodiments of the disclosure, the gate spacers 210 in the fin cut opening 218 and gate cut openings 224 may or may not be thinned. FIGS. 7A and 7B are cross-sectional views of the FinFET device 200 after thinning the gate spacers 210, the thinned gate spacers are depicted as 210a in the fin cut opening 218 and the gate cut openings 224. The second OPL 220b is stripped prior to thinning the gate spacers 210 using a conventional material removing process operation. Advantageously, the thinned gate spacers 210a will reduce the dielectric constant of the single diffusion break structure 106 and gate cut structures 108, and therefore lowering the parasitic capacitance of the structures. The thinned gate spacers 210a also allow a greater volume of lower-k dielectric material to be filled in the single diffusion break and gate cut structures (106 and 108, respectively) in subsequent process operation. In one embodiment of the disclosure, the thinned gate spacers 210a have a width ranging from 1 to 5 nm, with a preferred width of 3 nm.

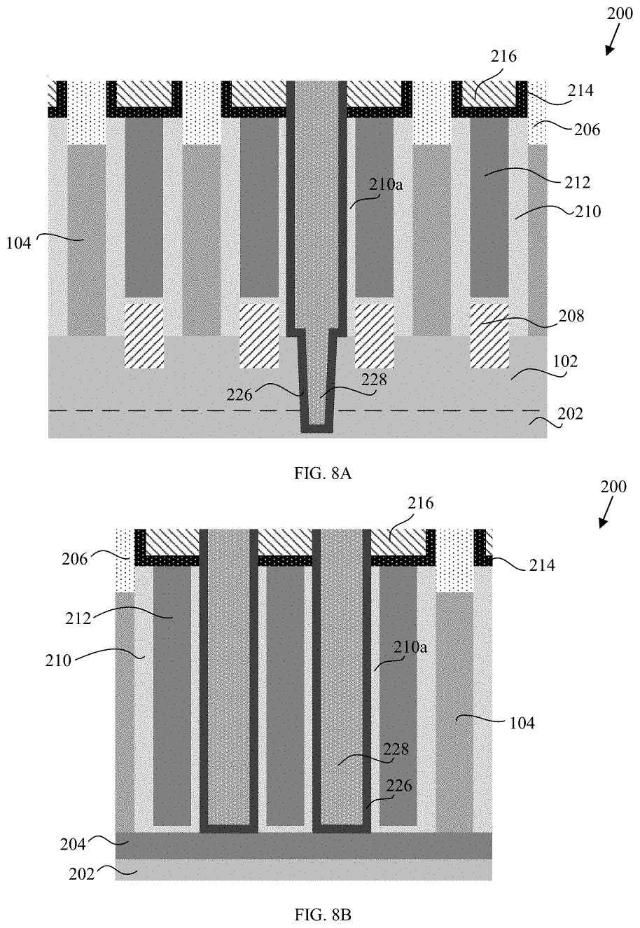

FIGS. 8A and 8B are cross-sectional views of the FinFET device 200 after depositing a second liner 226 and a fourth dielectric layer 228 in the fin cut and gate cut openings (218 and 224, respectively). In an alternative embodiment of the disclosure, the deposition of the second liner 226 may be omitted to maximize the volume of the fourth dielectric layer 228 to be deposited in the fin cut and gate cut openings (218 and 224, respectively). As illustrated in FIGS. 8A and 8B, the second liner 226 is conformally deposited in the fin cut and gate cut openings (218 and 224, respectively) by conventional deposition process operation, such as chemical vapor deposition process. In one embodiment of the disclosure, the second liner 226 may be formed of a suitable material, such as SiN, with a thickness ranging from 0 to 5 nm.

The fourth dielectric layer 228 is subsequently deposited in the fin cut and gate cut openings (218 and 224, respectively), defining intermediate structures of the single diffusion break structure 106 and the gate cut structures 108. A conventional planarization process operation may be performed to form a planar surface such that the fourth dielectric layer 228 is contained within the fin cut and gate cut openings (218 and 224, respectively). In one embodiment of the disclosure, the fourth dielectric layer 228 is preferred to be a porous low-k material having a lower dielectric constant than the second liner 226. In another embodiment of the disclosure, the dielectric constant of the fourth dielectric layer 228 is preferred to be lower than 3.9. The porous low-k material enables parasitic capacitance in the single diffusion break and gate cut structures (106 and 108, respectively) to be kept low. In yet another embodiment of the disclosure, the fourth dielectric layer 228 includes a silicon-containing material such as silicon dioxide or a carbon-doped silicon oxide material containing silicon, carbon, oxygen and hydrogen (SiOCH).

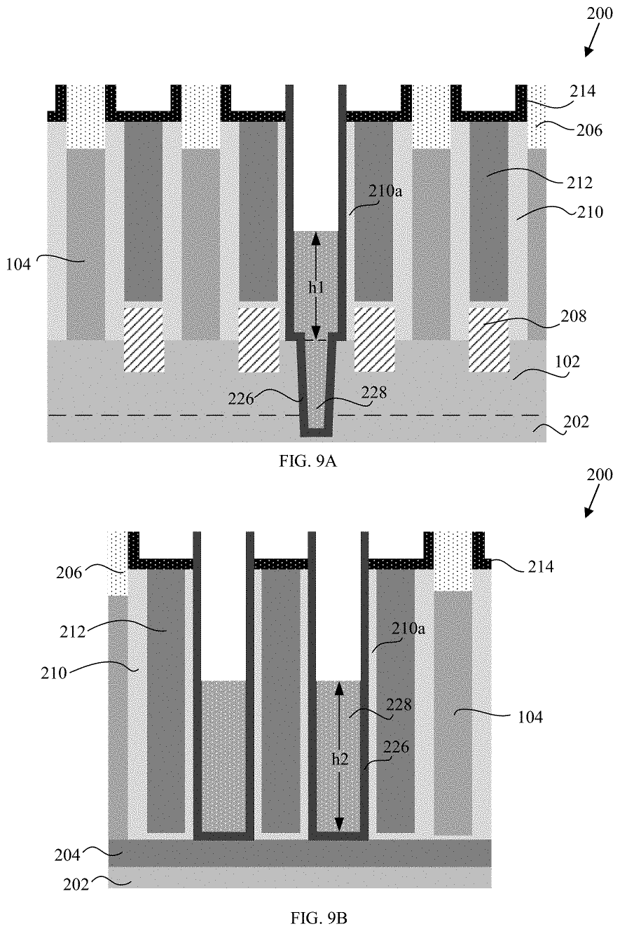

FIGS. 9A and 9B are cross-sectional views of the FinFET device 200 after recessing the fourth dielectric layer 228. A conventional material removing process operation is employed to concurrently recess the fourth dielectric layer 228 in the fin cut and gate cut openings (218 and 224, respectively). Due to the similarity in material properties of the third dielectric layer 216 and the fourth dielectric layer 228, the exposed third dielectric layer 216 is also removed in the process. The first liner 214, which is preferred to have a high etch selectivity to the third dielectric layer 216, will remain predominantly intact during the material removing process operation and functions as a protective layer to the underlying materials. In one embodiment of the disclosure, the recessed fourth dielectric layer 228 has a first height h1 ranging from 30 to 50 nm over a top surface of the fin 102, as illustrated in FIG. 9A. The recessed fourth dielectric layer 228 has a second height h2 ranging from 20 to 100 nm over the first dielectric layer 204, as illustrated by FIG. 9B. In another embodiment of the disclosure, the recessed fourth dielectric layer 228 has a preferred height of 40 nm above the fin 102.

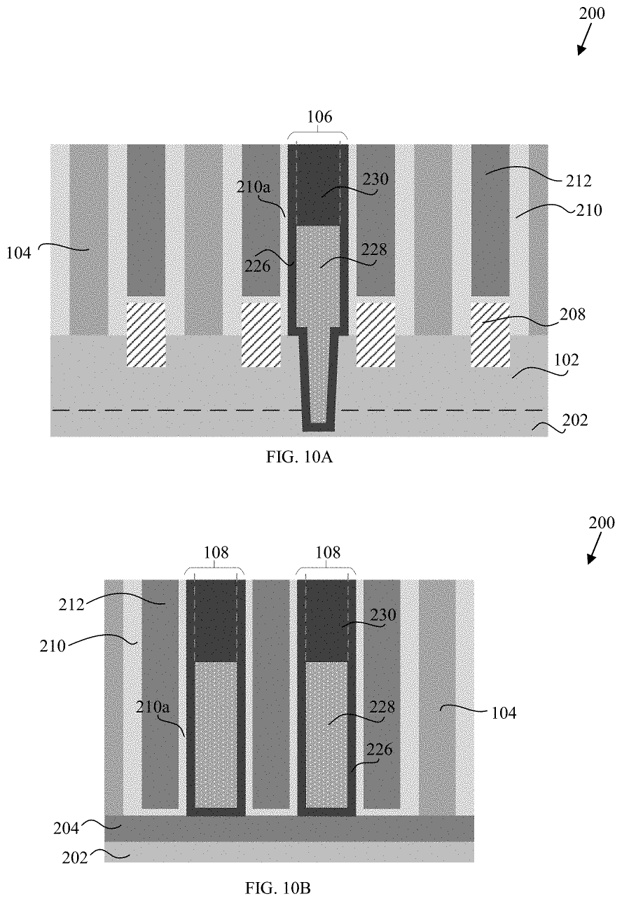

FIGS. 10A and 10B are cross-sectional views of the FinFET device 200 after forming the single diffusion break structure 106 and the gate cut structures 108. A capping layer 230 is deposited over the recessed fourth dielectric layer 228. In this embodiment, the capping layer 230 is formed of the same material as the second liner 226, but may also be formed of a different material. In another embodiment of the disclosure, the capping layer 230 has a higher k-value than the fourth dielectric layer 228.

The capping layer 230 and the second liner 226 enclose the fourth dielectric layer 228, increasing mechanical strength of the single diffusion break structure 106 and the gate cut structures 108. The capping layer 230 is preferred to have substantially high etch selectivity to the second dielectric layer 212, ensuring the capping layer 230 is kept predominantly intact during downstream process operations. A conventional planarization process operation is employed to form a planar surface by removing the hard mask layer 206, the first liner 214, upper portions of the second dielectric layer 212 and upper portions of the gate spacers 210. In this embodiment of the disclosure, the capping layer 230 is SiN.

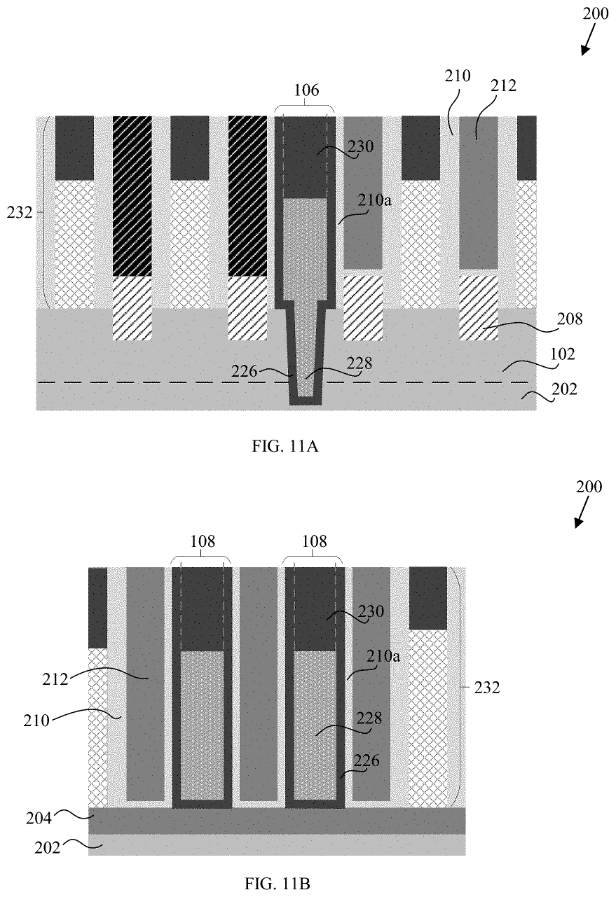

FIGS. 11A and 11B are cross-sectional views of the FinFET device 200 after a plurality of processes to form replacement gate structures 232. The processes may include one or more deposition process operations to form a gate insulation layer (e.g., silicon dioxide, hafnium oxide or a high-k material) and one or more conductive layers (e.g., barrier layers, seed layers, work function material layers and fill layers) that will be part of a gate electrode of the replacement gate structure 232 (layers are not separately shown). The conductive layers may be planarized and/or recessed.

In the above detailed description, a method of concurrently forming a single diffusion break and gate cut structures of FinFET semiconductor devices and the resulting semiconductor device are presented. By enclosing a porous low-k dielectric material with a dielectric material of higher dielectric constant in a single diffusion break structure and gate cut structures, parasitic capacitance of the structures can be kept low while maintaining a robust structure. As a result of the fin cut and gate cut processes are effectuated using a single hard mask layer, the process flow is shortened, thereby increasing throughput and reducing manufacturing costs. Moreover, it should be appreciated by those skilled in the art, after a complete reading of the disclosure, forming of the single diffusion break structure and the gate cut structures may be performed separately and not necessary be performed concurrently.

The terms “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the device described herein are, for example, capable of operation in other orientations than those illustrated or otherwise described herein.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in one embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

While several exemplary embodiments have been presented in the above detailed description of the device, it should be appreciated that number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

1. A method of forming a semiconductor device comprising:
providing a first gate structure, a second gate structure, a third gate structure, and a fourth gate structure;
and
forming a diffusion break structure and a gate cut structure between the first and second gate structures and a gate cut structure between the third and fourth gate structures;
wherein the diffusion break structure and the gate cut structure each comprise a first dielectric material in a lower portion thereof and a second dielectric material over the first dielectric material.

2. The method of claim 1, wherein forming the fin cut opening and the gate cut opening, further comprises:
depositing a first liner over the first and second sacrificial gate structures;
depositing a third dielectric layer over the first liner, wherein the first liner and the third dielectric layer have a high etch selectivity between them that permits selective removal of one without affecting the other.

3. The method of claim 1, wherein forming the fin cut opening and the gate cut opening exposes gate spacers on sidewalls of the openings.

4. The method of claim 3 wherein the exposed spacers are thinned to a thickness ranging from 1 to 5 nm.

5. The method of claim 1, wherein the fin cut opening and the gate cut opening comprise sidewalls and bottom surfaces, further comprises:
depositing a second liner in the fin cut opening and the gate cut opening, covering the sidewalls and the bottom surfaces of the openings.

6. The method of claim 1, wherein the recessed first dielectric layer in the fin cut opening has a height ranging from 30 to 50 nm above the fin.

7. The method of claim 1, wherein the deposited first dielectric layer has a lower dielectric constant than the second dielectric layer.

8. The method of claim 1, wherein the deposited first dielectric layer comprises a silicon-containing layer.

9. A semiconductor device comprising:
a first gate structure and a second gate structure;
a diffusion break structure between the first and second gate structures;
a third gate structure and a fourth gate structure; and
a gate cut structure between the third and fourth gate structures,
wherein the diffusion break structure and the gate cut structure each comprise a first dielectric material in a lower portion thereof and a second dielectric material over the first dielectric material.

10. The semiconductor device of claim 9 wherein the first dielectric material has a lower dielectric constant than the second dielectric material.

11. The semiconductor device of claim 9 includes at least one fin and the first dielectric layer in the diffusion break structure has a height ranging from 30 to 50 nm above a top surface of the fin.

12. The semiconductor device of claim 9 wherein the first dielectric material comprises a silicon-containing material.

13. The semiconductor device of claim 9, further comprises:
a first gate spacer on sidewalls of the diffusion break structure; and
a second gate spacer on sidewalls of the first and second gate structures, wherein the first gate spacer has a smaller width than the second gate spacer.

14. The semiconductor device of claim 13 wherein the first gate spacer has a width ranging from 1 to 5 nm.

15. The semiconductor device of claim 9 further comprises a liner enclosing the diffusion break structure and the gate cut structure.

16. The semiconductor device of claim 15, wherein the liner has a width 5 nm or less.

17. The semiconductor device of claim 16, wherein the liner comprises SiN.

18. A semiconductor device comprising:
a first gate structure;
a second gate structure; and
a diffusion break structure between the first gate structure and the second gate structure, wherein the diffusion break structure comprises a first dielectric material in a lower portion thereof and a second dielectric material over the first dielectric material.

19. The semiconductor device of claim 18 wherein the first dielectric material has a lower dielectric constant than the second dielectric material.

20. The semiconductor device of claim 19 wherein the first dielectric material has a dielectric constant lower than 3.9.
